(19) United States
(12) Patent Application Publication
(10) Pub. No.: US 2025/0254906 A1
(43) Pub. Date: Aug. 7, 2025

(54) SEMICONDUCTOR DEVICE AND METHOD OF FORMING THEREOF

(71) Applicant: TAIWAN SEMICONDUCTOR MANUFACTURING COMPANY, LTD., Hsinchu (TW)

(72) Inventors: Po-Kang HO, Taoyuan City (TW); Tsai-Yu Huang, Taoyuan City (TW); Li-Ting Wang, Hsinchu City (TW); Chi On CHUI, Hsinchu City (TW)

(73) Assignee: TAIWAN SEMICONDUCTOR MANUFACTURING COMPANY, LTD., Hsinchu (TW)

(21) Appl. No.: 18/434,559

(22) Filed: Feb. 6, 2024

(51) Int. Cl. H01L 29/78; H01L 29/06; H01L 29/417; H01L 29/423; H01L 29/66; H01L 29/775; H01L 29/786

(52) U.S. Cl. CPC H10D 30/62; H10D 30/014; H10D 30/024; H10D 30/43; H10D 30/6219; H10D 30/6735; H10D 30/6757; H10D 62/121; H10D 64/017

(57) ABSTRACT

A method includes a number of operations. A semiconductor fin is formed and extends from a substrate. A dummy gate structure is formed across the semiconductor fin. An exposed surface of the gate layer is converted into a surface modification layer over the gate layer. Source/drain regions are formed on the semiconductor fin. The dummy gate structure is removed. A gate structure is formed over the semiconductor fin and extends between the source/drain regions and in the surface modification layer.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a Fin Field-Effect Transistor (FinFET), in accordance with some embodiments.

FIGS. 2-4, 5A-5B, 6A-6E, 7A-7D, 8A-8C, 9A-9B and 10A-10E illustrate various views of a FinFET device at various stages of fabrication, in accordance with some embodiments.

FIG. 11 is a perspective view of a gate-all-around (GAA) FET device, in accordance with some embodiments.

FIG. 12 illustrates a perspective view of forming a dummy gate structure to form a GAA-FET, in accordance with some embodiments.

FIGS. 13A-13E illustrate various views of a GAA-FET, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The present disclosure is generally related to semiconductor device such as integrated circuit (IC) structures and methods of forming the same, and more particularly to fabricating fin field effect transistors (FinFET), and/or gate-all-around (GAA) transistors, planar transistors. It is also noted that the present disclosure presents embodiments in the form of multi-gate transistors. Multi-gate transistors include those transistors whose gate structures are formed on at least two-sides of a channel region. These multi-gate devices may include a p-type metal-oxide-semiconductor device or an n-type metal-oxide-semiconductor device. Specific examples may be presented and referred to herein as FinFET, on account of their fin-like structure. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), and/or other suitable channel configuration. Presented herein are embodiments of devices that may have one or more channel regions (e.g., nanosheets) associated with a single, contiguous gate structure. However, one of ordinary skill would recognize that the teaching can apply to a single channel (e.g., single nanosheet) or any number of channels. One of ordinary skill may recognize other examples of semiconductor devices that may benefit from aspects of the present disclosure.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

In one or more embodiments of the present disclosure, formation of semiconductor devices may include forming a dummy gate structure over a semiconductor fin structure. For example, the dummy gate structure may include an oxide layer used as a dummy dielectric layer covering the semiconductor fin structure and a polysilicon layer or crystal silicon layer used as a dummy gate layer over the oxide layer of the dummy dielectric layer. Formation of the dummy gate structure may include patterning the polysilicon layer of the dummy gate layer by hard mask, and poly residues of the polysilicon layer may extend out of the hard mask and remain at corners of the dummy gate structure and the semiconductor fin structure. Replacement gate process may be performed to the dummy gate structure and the formed replacement gate may extend to gaps formed by sidewalls of formed source/drain regions and spacers. The unintended extension of the formed replacement gate may include high-k dielectric material, which increases parasitic capacitance and results in AC degradation in terms of electrical properties.

In one or more embodiments of the present disclosure, a surface modification process may be performed to the dummy gate structure after a dummy gate layer such as polysilicon layer of crystal silicon layer of the dummy gate structure is patterned, which in turn forms a surface modification layer over the of the dummy gate structure. Because the surface modification layer has a different material composition than initial material composition of the dummy gate layer, the surface modification layer is not removed during the replacement gate process and thus remains in the gaps formed by the sidewalls of the formed source/drain regions and the spacers, which in turn prevents the replacement gate structure from unintentionally formed in such gaps formed by the sidewalls of the formed source/drain regions and the spacers, thus reducing leakage current. In some embodiments, the surface modification layer may be an oxide layer having low dielectric constant, and thus the parasitic capacitance in the semiconductor device may be reduced.

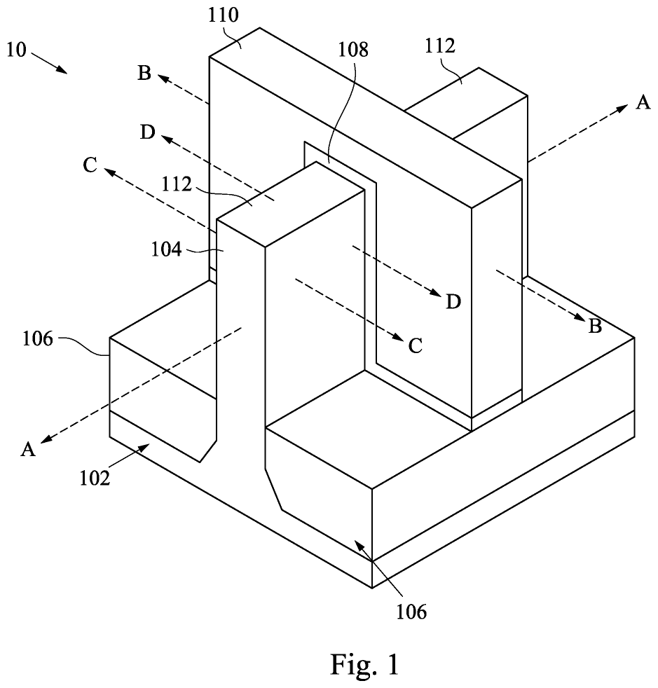

FIG. 1 illustrates an example of a FinFET 10 in a perspective view. The FinFET 10 includes a substrate 102 and a fin 104 protruding above the substrate 102. Isolation regions 106 are formed on opposing sides of the fin 104, with the fin 104 protruding above the isolation regions 106. A gate dielectric 108 is along sidewalls and over a top surface of the fin 104, and a gate electrode 110 is over the gate dielectric 108. Source/drain regions 112 are in the fin 104 and on opposing sides of the gate dielectric 108 and the gate electrode 110. FIG. 1 further illustrates reference cross-sections that are used in later figures. Cross-section B-B extends along a longitudinal axis of the gate electrode 110 of the FinFET 10. Cross-section A-A is perpendicular to cross-section B-B and is along a longitudinal axis of the fin 104 and in a direction of, for example, a current flow between the source/drain regions 112. Cross-section C-C is parallel to cross-section B-B and is across the source/drain region 112. Cross-section D-D is parallel to cross-section B-B and is across a region between the gate electrode 110 and the source/drain region 112. Subsequent figures refer to these reference cross-sections for clarity.

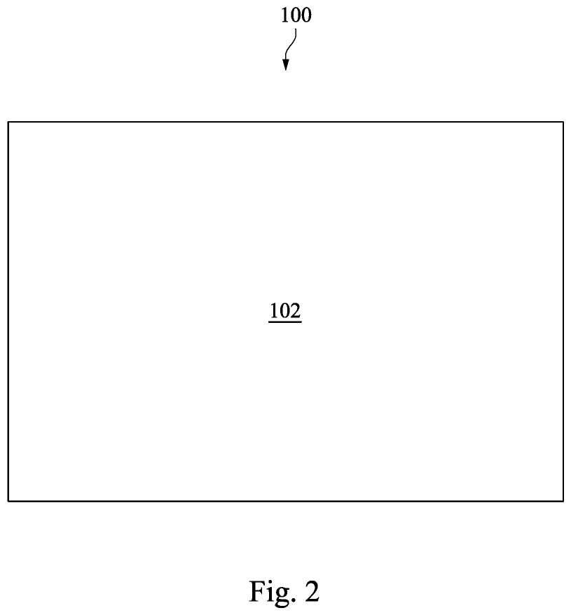

FIGS. 2-4, 5A-5B, 6A-6E, 7A-7D, 8A-8C, 9A-9B and 10A-10E illustrate various views of a FinFET device 100 at various stages of fabrication, in accordance with some embodiments. The FinFET device 100 is similar to the FinFET 10 in FIG. 1, but with multiple fins and multiple gate structures.

FIGS. 2-4 illustrate cross-sectional views of the FinFET device 100 along cross-section B-B.

FIG. 2 illustrates a cross-sectional view of a substrate 102. The substrate 102 may be a semiconductor substrate, such as a bulk semiconductor, a semiconductor-on-insulator (SOI) substrate, or the like, which may be doped (e.g., with a p-type or an n-type dopant) or undoped. The substrate 102 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 102 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GalnP, and/or GaInAsP; or combinations thereof.

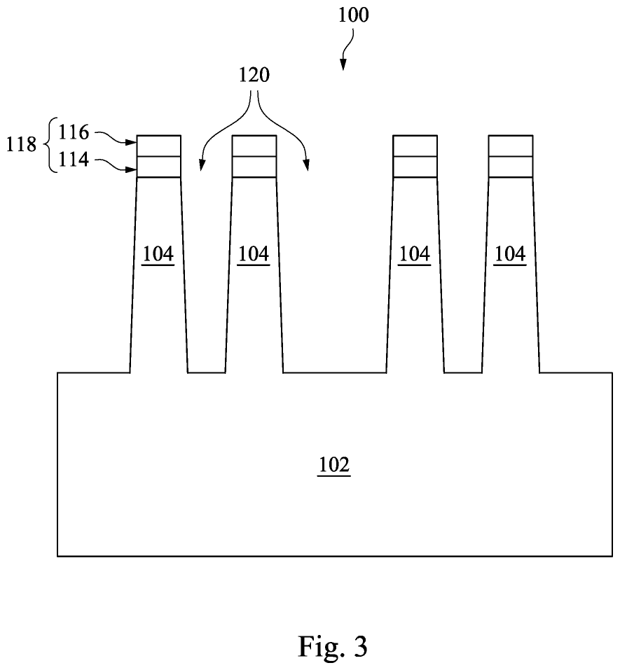

Referring next to FIG. 3, the substrate 102 shown in FIG. 2 is patterned using, for example, photolithography and etching techniques. For example, a mask layer, such as a pad oxide layer 114 and an overlying pad nitride layer 116, is formed over the substrate 102. The pad oxide layer 114 may be a thin film comprising silicon oxide formed, for example, using a thermal oxidation process. The pad oxide layer 114 may act as an adhesion layer between the substrate 102 and the overlying pad nitride layer 116 and may act as an etch stop layer for etching the pad nitride layer 116. In some embodiments, the pad nitride layer 116 is formed of silicon nitride, silicon oxynitride, silicon carbonitride, the like, or a combination thereof, and may be formed using low-pressure chemical vapor deposition (LPCVD) or plasma enhanced chemical vapor deposition (PECVD), as examples.

The mask layer may be patterned using photolithography techniques. Generally, photolithography techniques utilize a photoresist material (not shown) that is deposited, irradiated (exposed), and developed to remove a portion of the photoresist material. The remaining photoresist material protects the underlying material, such as the mask layer in this example, from subsequent processing steps, such as etching. In this example, the photoresist material is used to pattern the pad oxide layer 114 and pad nitride layer 116 to form a patterned mask 118, as illustrated in FIG. 3.

The patterned mask 118 is subsequently used to pattern exposed portions of the substrate 102 to form trenches 120, thereby defining semiconductor fins 104 (may also be referred to as fins) between adjacent trenches 120 as illustrated in FIG. 3. In some embodiments, the semiconductor fins 104 are formed by etching trenches in the substrate 102 using, for example, reactive ion etch (RIE), neutral beam etch (NBE), the like, or a combination thereof. The etch may be anisotropic. In some embodiments, the trenches 120 may be strips (viewed from in the top) parallel to each other, and closely spaced with respect to each other. In some embodiments, the trenches 120 may be continuous and surround the semiconductor fins 104. After semiconductor fins 104 are formed, the patterned mask 118 may be removed by etching or any suitable method.

The fins 104 may be patterned by any suitable method. For example, the fins 104 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one or more embodiments, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins 104.

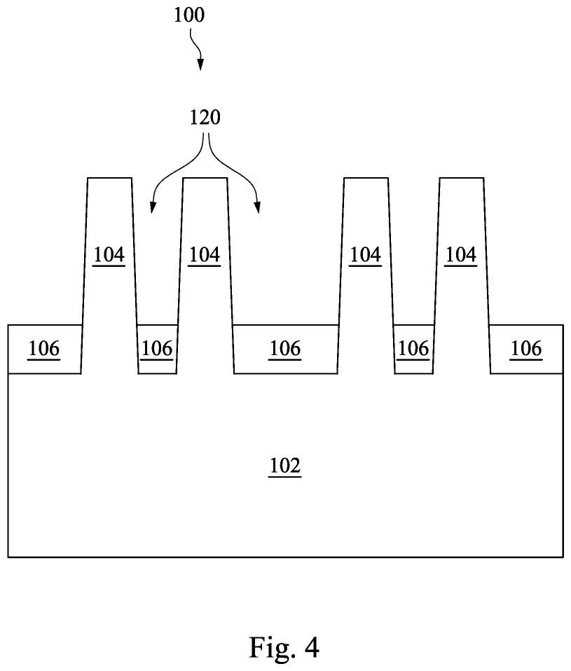

Next, FIG. 4 illustrates the formation of an insulation material between neighboring semiconductor fins 104 to form isolation regions 106. The insulation material may be an oxide (e.g., silicon oxide), a nitride, the like, or a combination thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials and/or other formation processes may be used. In the illustrated embodiment, the insulation material is silicon oxide formed by a FCVD process. An anneal process may be performed after the insulation material is formed. A planarization process, such as a chemical mechanical polish (CMP), may remove any excess insulation material (and, if present, the patterned mask 118) and form top surfaces of the isolation regions 106 and top surfaces of the semiconductor fins 104 that are coplanar (not shown).

In some embodiments, the isolation regions 106 include a liner, e.g., a liner oxide (not shown), at the interface between the isolation region 106 and the substrate 102/semiconductor fins 104. In some embodiments, the liner oxide is formed to reduce crystalline defects at the interface between the substrate 102 and the isolation region 106. Similarly, the liner oxide may also be used to reduce crystalline defects at the interface between the semiconductor fins 104 and the isolation region 106. The liner oxide (e.g., silicon oxide) may be a thermal oxide formed through a thermal oxidation of a surface layer of substrate 102, although other suitable method may also be used to form the liner oxide.

Next, the isolation regions 106 are recessed to form shallow trench isolation (STI) regions. The isolation regions 106 are recessed such that the upper portions of the semiconductor fins 104 protrude from between neighboring isolation regions 106. The top surfaces of the isolation regions 106 may have a flat surface (as illustrated), a convex surface, a concave surface (such as dishing), or a combination thereof. The top surfaces of the isolation regions 106 may be formed flat, convex, and/or concave by an appropriate etch. The isolation regions 106 may be recessed using an acceptable etching process, such as one that is selective to the material of the isolation regions 106. For example, a chemical oxide removal using dilute hydrofluoric (dHF) acid may be used.

FIGS. 2 through 4 illustrate some embodiments of forming fins 104, but fins may be formed in various different processes. In one example, a dielectric layer can be formed over a top surface of a substrate; trenches can be etched through the dielectric layer; homoepitaxial structures can be epitaxially grown in the trenches; and the dielectric layer can be recessed such that the homoepitaxial structures protrude from the dielectric layer to form fins. In another example, heteroepitaxial structures can be used for the fins. For example, the semiconductor fins can be recessed, and a material different from the semiconductor fins may be epitaxially grown in their place.

In an even further example, a dielectric layer can be formed over a top surface of a substrate; trenches can be etched through the dielectric layer; heteroepitaxial structures can be epitaxially grown in the trenches using a material different from the substrate; and the dielectric layer can be recessed such that the heteroepitaxial structures protrude from the dielectric layer to form fins.

In some embodiments where homoepitaxial or heteroepitaxial structures are epitaxially grown, the grown materials may be in situ doped during growth, which may obviate prior and subsequent implantations although in situ and implantation doping may be used together. Still further, it may be advantageous to epitaxially grow a material in an NMOS region different from the material in a PMOS region. In various embodiments, the fins may comprise silicon germanium (SiₓGe₁₋ₓ, where x can be between approximately 0 and 1), silicon carbide, pure or substantially pure germanium, a III-V compound semiconductor, a II-VI compound semiconductor, or the like. For example, the available materials for forming III-V compound semiconductor include, but are not limited to, InAs, AlAs, GaAs, InP, GaN, InGaAs, InAlAs, GaSb, AlSb, AlP, GaP, and the like.

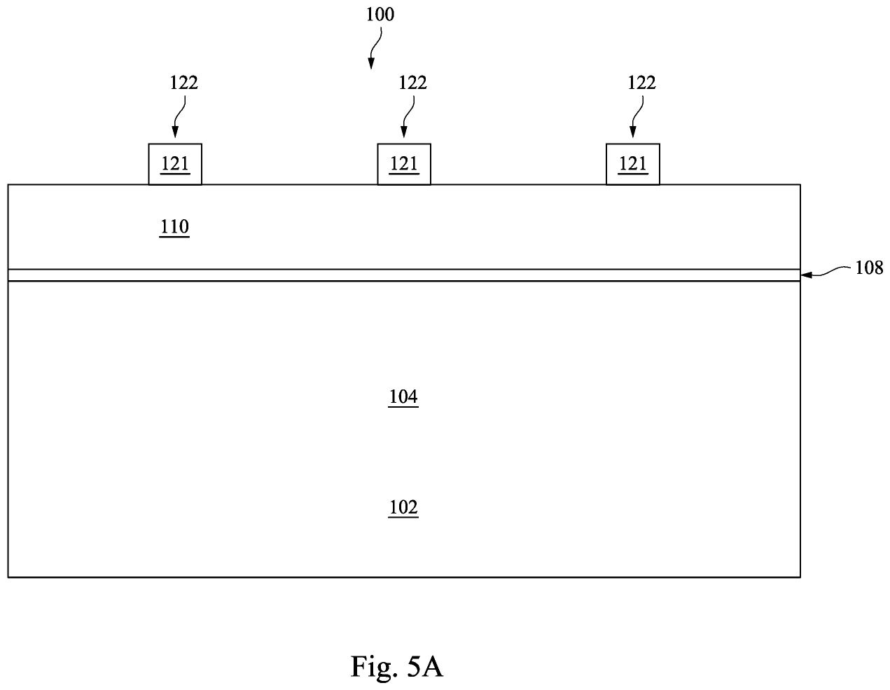

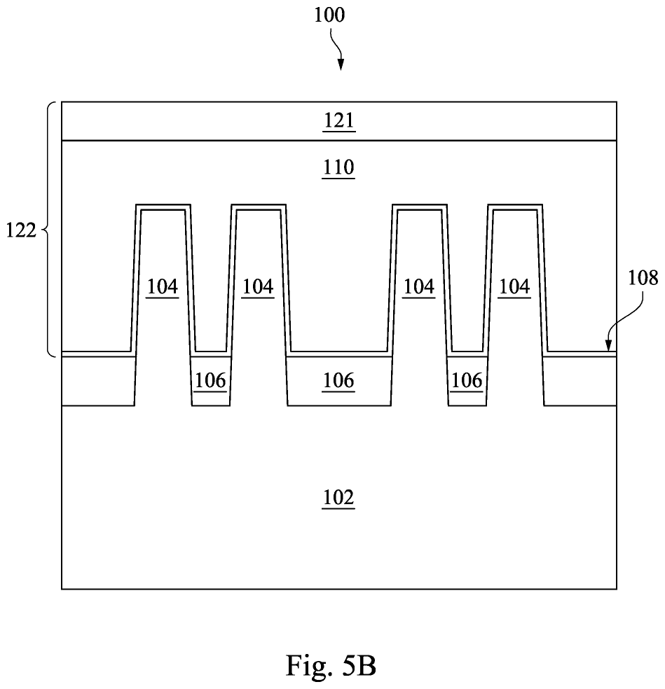

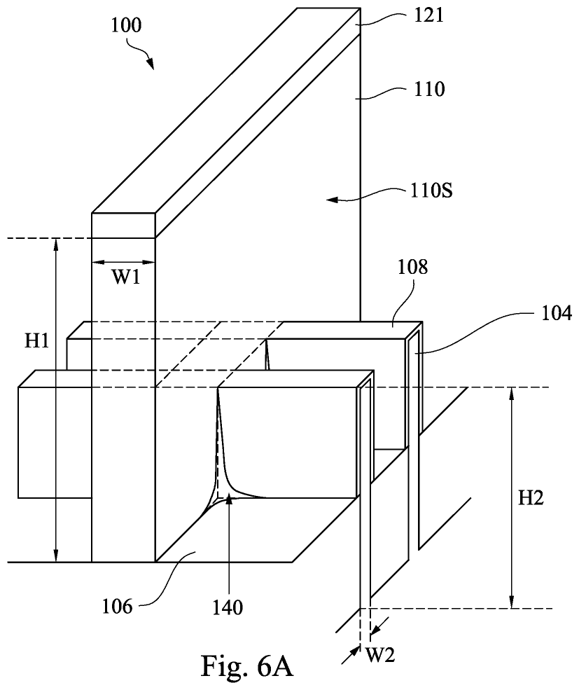

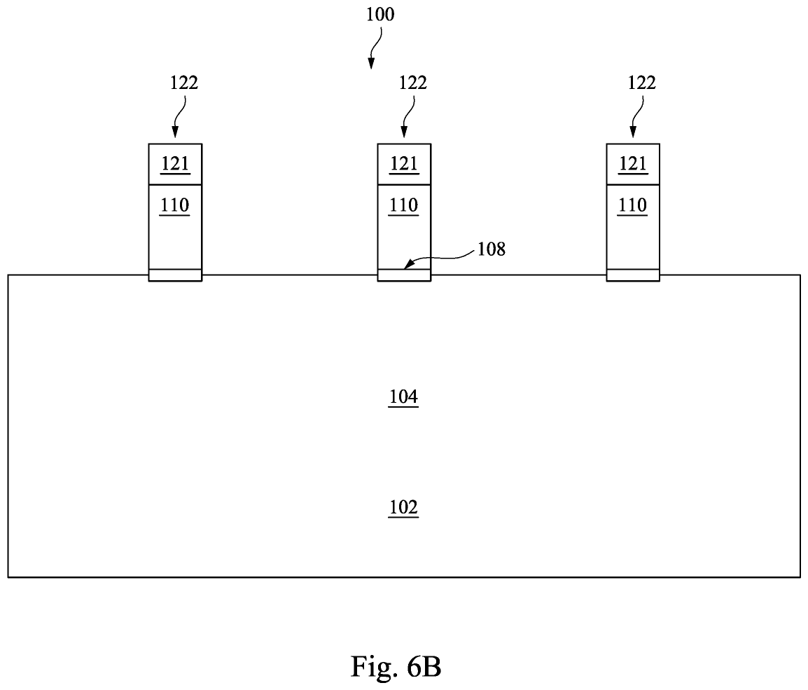

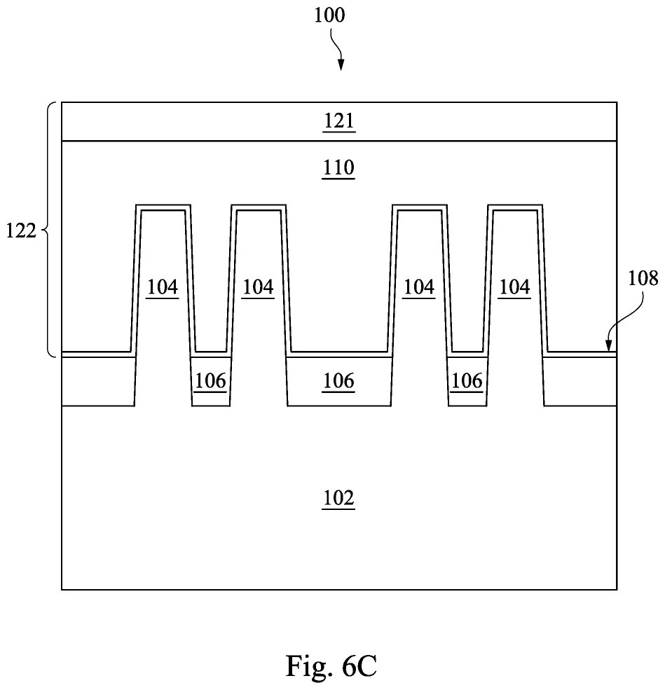

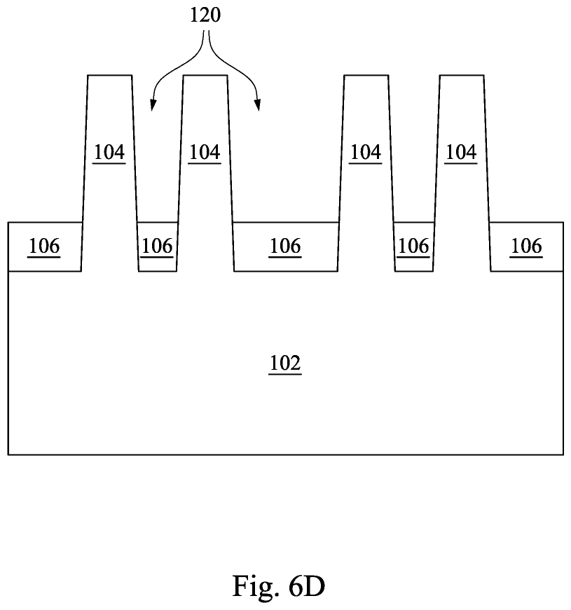

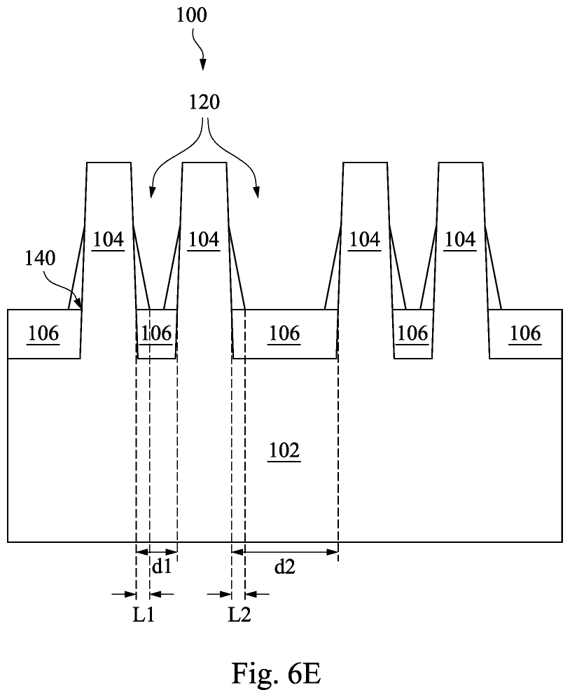

Reference is made to FIGS. 5A-6E. FIGS. 5A-6E illustrates formation of dummy gate structures 122 over the semiconductor fins 104.

Referring to FIGS. 5A and 5B. FIG. 5A illustrates a cross-sectional view of the FinFET device 100 along cross-section A-A, and FIG. 5B illustrates a cross-sectional view along cross-section B-B. The dummy gate structures 122 each include gate dielectric 108 and gate 110, in some embodiments. The dummy gate structure 122 may be formed by patterning a mask layer, a gate layer and a gate dielectric layer, where the mask layer, the gate layer and the gate dielectric layer comprise a same material as the mask 121, the gate 110, and the gate dielectric 108, respectively.

As illustrated in FIGS. 5A and 5B, to form the dummy gate structures 122, the gate dielectric layer 108 is formed on the semiconductor fins 104 and the isolation regions 106. The gate dielectric layer 108 may be, for example, silicon oxide, silicon nitride, multilayers thereof, or the like, and may be deposited or thermally grown according to acceptable techniques. The formation methods of the gate dielectric layer may include molecular-beam deposition (MBD), atomic layer deposition (ALD), plasma-enhanced CVD (PECVD), and the like.

The gate layer 110 is formed over the gate dielectric layer 108, and the mask layer 121 is formed over the gate layer. The gate layer may be deposited over the gate dielectric layer and then planarized, such as by a CMP. The mask layer may be deposited over the gate layer. The gate layer 110 may be formed of, for example, polysilicon or crystal silicon, although other materials may also be used. The mask layer 121 may be formed of, for example, silicon nitride or the like.

After the gate dielectric layer 108, the gate layer 110, and the mask layer 121 are formed, the mask layer 121 may be patterned using acceptable photolithography and etching techniques to form mask 121. The pattern of the mask 121 may then be transferred to the gate layer 110 and the gate dielectric layer 108 by a suitable etching technique to form gates 110 and gate dielectrics 108, respectively. Reference is made to FIGS. 6A through 6E to illustrate patterning the gate layer 110.

FIG. 6A illustrates a schematic perspective view of residues at corners of the semiconductor fin structures and patterned dummy gate layer, FIG. 6B illustrates a cross-sectional view of the FinFET device 100 along cross-section A-A, FIG. 6C illustrates a cross-sectional view along cross-section B-B, FIG. 6D illustrates a cross-sectional view along cross-section C-C, and FIG. 6E illustrates a cross-sectional view along cross-section D-D.

FIG. 6A illustrates the gate layer 110 is patterned. As illustrated in FIGS. 6B and 6C, each gate 110 and a corresponding gate dielectric 108 collectively serve as a dummy gate structure 122 that wrap around channel regions of the semiconductor fins 104. The gate 110 may also have a lengthwise direction substantially perpendicular to the lengthwise direction of respective semiconductor fins 104. In some embodiments, the patterned gate layer 110 may have a height H1 in a range from 100 nm to 200 nm and have a width W1 in a range from 10 nm to 50 nm. In some embodiments, the semiconductor fin 104 may have a height H2 in a range from 50 nm to 80 nm and have a width W1 in a range from 5 nm to 10 nm.

As illustrated in FIG. 6A, after the gate layer 110 is patterned, polysilicon residues 140 of the gate layer 110 may remain at corners of the gate dielectric layer 108 over the semiconductor fins 104 and exposed sidewalls 110s of the gate layer 110 under the mask 121. The residues 140 of the gate layer 110 have cone-shaped profiles that extend outward from intersection points of the exposed sidewalls 110s of the gate layer 110 and the gate dielectric 108 to top surfaces of the isolation regions 106. FIGS. 6D and 6E illustrates that the residues 140 extend over the side walls of gate dielectric layer 108 adjacent the patterned gate layer 110.

In FIG. 6E, different distances d1 and d2 are between the semiconductor fins 104 in the horizontal direction. The distance d1 is between the left immediately-adjacent two of the semiconductor fins 104 or between the right immediately-adjacent two of the semiconductor fins 104 in the horizontal direction. The distance d2 is greater than the distance d1. In other words, each of the trenches 120 may have a width d1 or a width d2 in the horizontal direction. In one or more embodiments, the residue 140 in the trench 120 with the distance d1 has a horizontal length L1, the residue 140 in the trench 120 with the distance d2 has a horizontal length L2, and the horizontal length L1 is greater than the horizontal length L2. That is, more volumes of the residues 140 of the patterned gate layer 110 remain in the trenches 120 corresponding to the distance d1 than in the trenches 120 corresponding to the distance d2. In one or more embodiments of the present disclosure, the horizontal length L1 is less than a half of the distance d1. The adjacent residues 140 in the same trench 120 may not merge together.

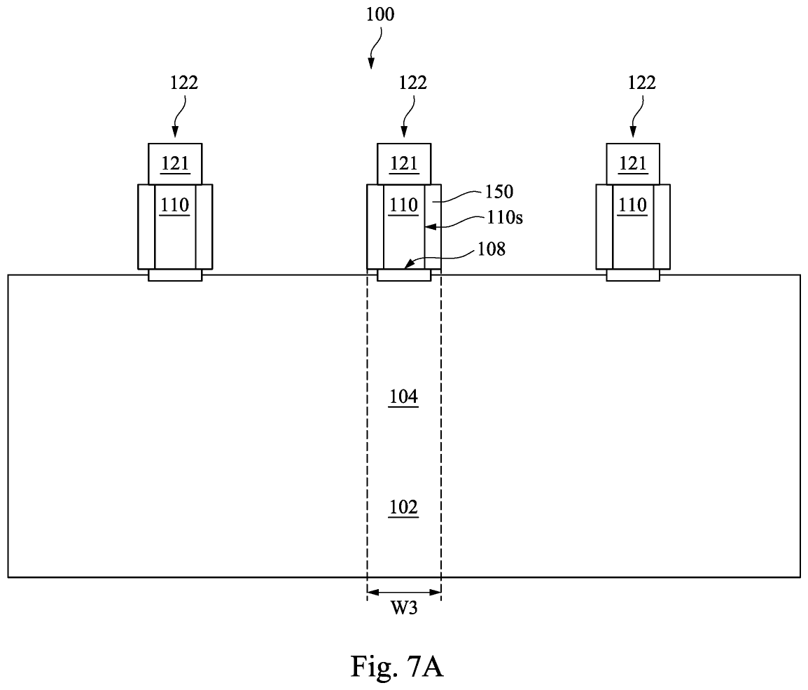

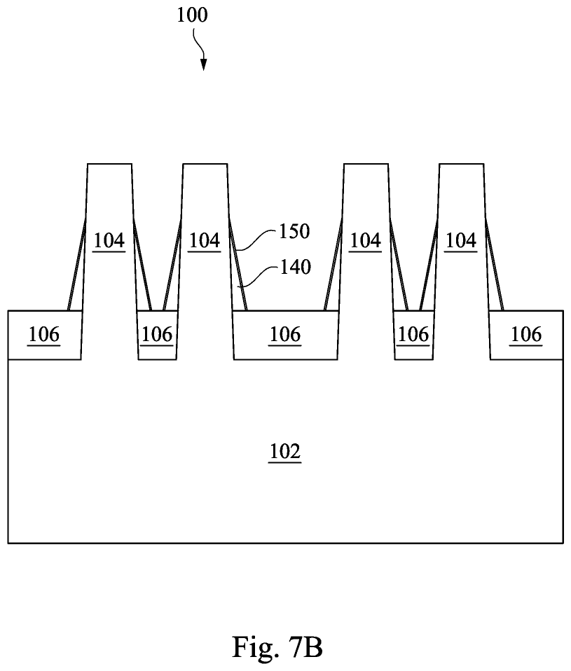

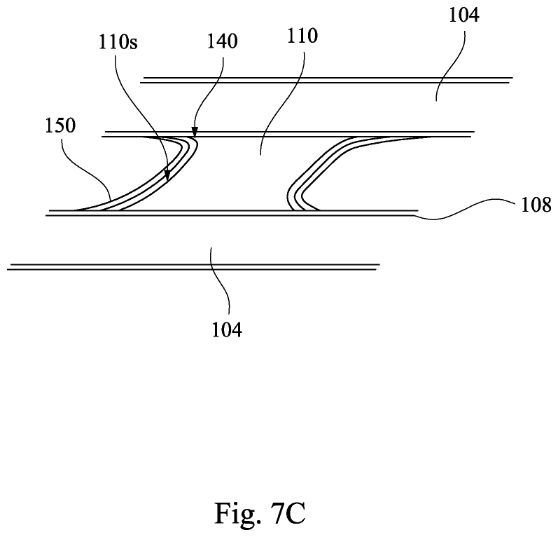

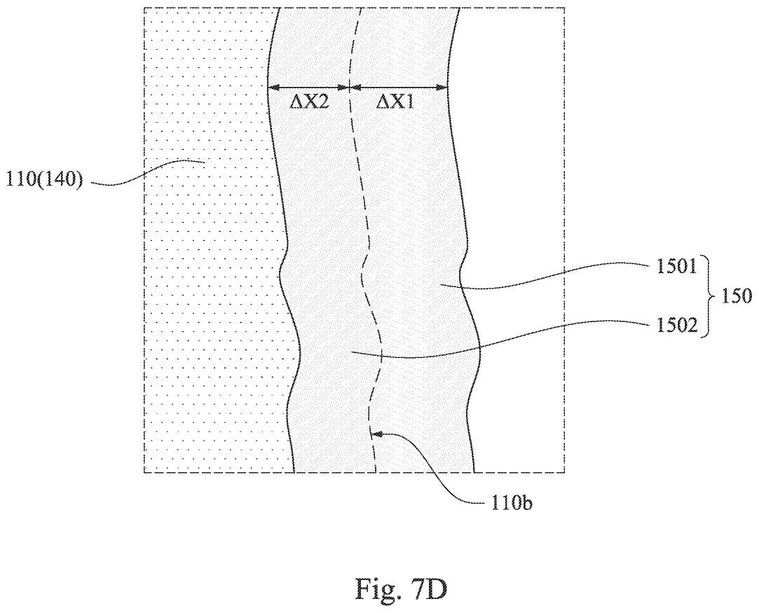

Reference is made to FIGS. 7A through 7D to illustrate a surface modification process performed to modify the exposed portions of the gate layer 110 including the sidewalls 110s and the residues 140 of the gate layer 110. The surface modification process converts these exposed portions of the gate layer 110 into a plurality of surface modification layers 150 over the sidewalls 110s and the residues 140 of the gate layer 110. FIG. 7A illustrates a cross-sectional view of the FinFET device 100 along cross-section A-A, FIG. 7B illustrates a cross-sectional view of the FinFET device 100 along cross-section D-D, FIG. 7C illustrates a cross-sectional of the of the FinFET device 100 along a plane between the semiconductor fins, and FIG. 7D schematically illustrates oxidation of the exposed portions of the gate layer.

In one or more embodiments of the present disclosure, the exposed portions of the gate layer 110 may be modified by a thermal process. The thermal process can be rapid thermal anneal (RTA) process with oxygen gas or oxygen radical process to oxidize the exposed surfaces of the gate layer 110. In some embodiments, the gate layer 110 may be polysilicon or crystal silicon, and the surface modification layer 150 may include silicon oxide. In some embodiments, the gate dielectric layer 108 is an oxide layer and covers the fins 104, the composition of the gate dielectric layer 108 may not change during the oxidation of the gate layer 110, and the gate dielectric layer 108 may protect the fins 104 from oxidation.

As illustrated in FIGS. 7A and 7B, the surface modification layer 150 are formed over the sidewalls 110s and exposed surfaces of the residues 140. FIG. 7D illustrates an example oxidation of the gate layer 110 and formation of the surface modification layer 150. As shown in the schematically local cross-section view, an oxide layer 1501 is formed over an exposed surface (e.g., the sidewalls 110s and exposed surfaces of the residues 140) of the gate layer 110 by the thermal process. The oxide layer 1501 may have a thickness AX1. After the oxide layer 1501 is formed, a surface layer of the gate layer 110 is consumed and converted into a thin oxide layer 1502 with a thickness AX2. The thickness AX2 of the thin oxide layer 1502 presents an amount of the oxidized portions of the gate layer 110 including the residues 140. In some embodiment, the thickness AX2 of the thin oxide layer 1502 can be measured. For example, as illustrated in FIG. 7A, after the gate layer 110 is oxidized, a sum W3 of the thickness of one of the fins 104 and 2 times of a sum of the thicknesses AX1 and AX2 can be measured. By comparing the sum W3 and the width W1 of one of the fins 104 prior to the thermal process, the thicknesses AX1 and AX2 can be obtained according to a base line 110b corresponding to the sidewalls 110s or the exposed surfaces residues 140.

In some embodiments, the thickness AX2 of the oxide layer 1502, which corresponds to the mount of the oxidized portions of the gate layer 110 during the thermal process, can be determined according to the thickness AX1 of the oxide layer 1501. For example, a ratio of the thickness AX1 to the thickness AX2 can be experimentally obtained. After the gate layer 110 is oxidized, the thickness AX2 of the oxide layer 1502 can be determined according to the thicknesses AX1 of the oxide layer 1501 formed during the oxidation of the gate layer 110.

In some embodiments, a pre-trim process may be performed to the surface modification layer 150 to reduce the thickness AX1 of the oxide layer 1501.

As illustrated in FIG. 7A, the gate layer 110 is consumed so that boundaries of the sidewalls 110s of the gate layer 110 recede below the hard mask 121. The surface modification layers 150 extend outwards from spaces between the hard mask 121 and the gate dielectric layer 108. In FIG. 7B, the residues 140 are covered by the surface modification layers 150 and are surrounded by the surface modification layers 150, the gate dielectric layer 108 and the isolation regions 106. FIG. 7C illustrates a cross-sectional along a plane between the semiconductor fins 104, wherein the surface modification layers 150 extend between the gate dielectric layers 108 over the two adjacent fins 104.

In some embodiments, the operated range of temperature for RTA process to the gate dielectric layer 110 is from 600° C. to 800° C. In some embodiments, the operated range of soak time for RTA process to the gate dielectric layer 110 is from 10 s to 60 s. In some embodiments, the operated range of pressure for RTA process to the gate dielectric layer 110 is from 1 torr to 760 torr. In some embodiments, the oxygen content of RTA process to the gate dielectric layer 110 is from 500 ppm to 1%.

In some embodiments, the operated range of temperature for oxygen radical process to the gate dielectric layer 110 is from 200° C. to 550° C. In some embodiments, the operated range of plasma power for oxygen radical process to the gate dielectric layer 110 is from 2.5 kw to 6 kw. In some embodiments, the operated range of pressure for oxygen radical process to the gate dielectric layer 110 is 0.1 torr to 5 torr. In some embodiments, the operated range of oxygen gas flow rate for oxygen radical process to the gate dielectric layer 110 is 100 sccm to 1000 sccm.

In some embodiments, the surface modification of the gate layer 110 can be a nitration process through nitrogen-based process gas, so that the moderation layer 150 may be a nitride layer such as silicon nitride.

The formed surface modification layers 150 may not be removed during the subsequently gate replacement process so that the surface modification layers 150 may have occupied volume to reduce the expansion the formed replacement gate structure.

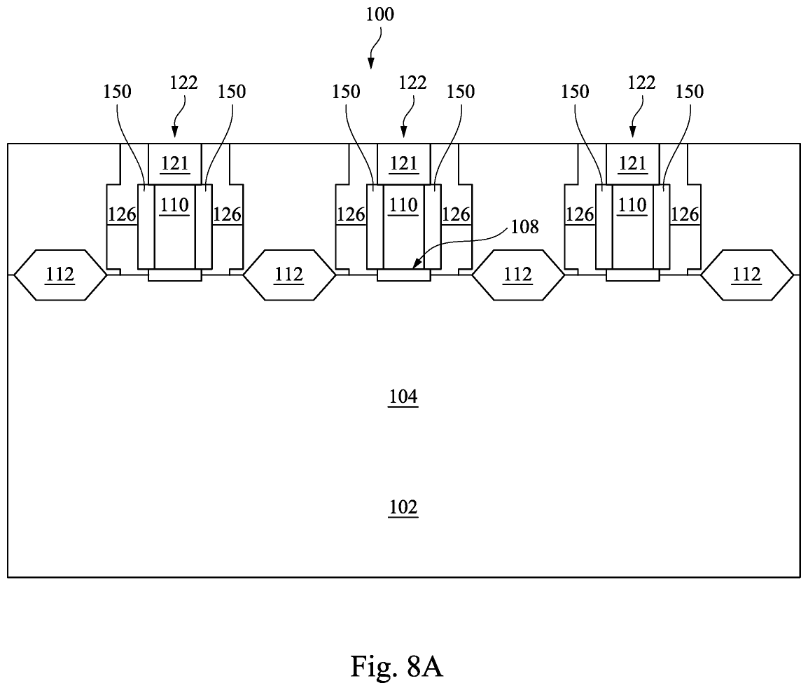

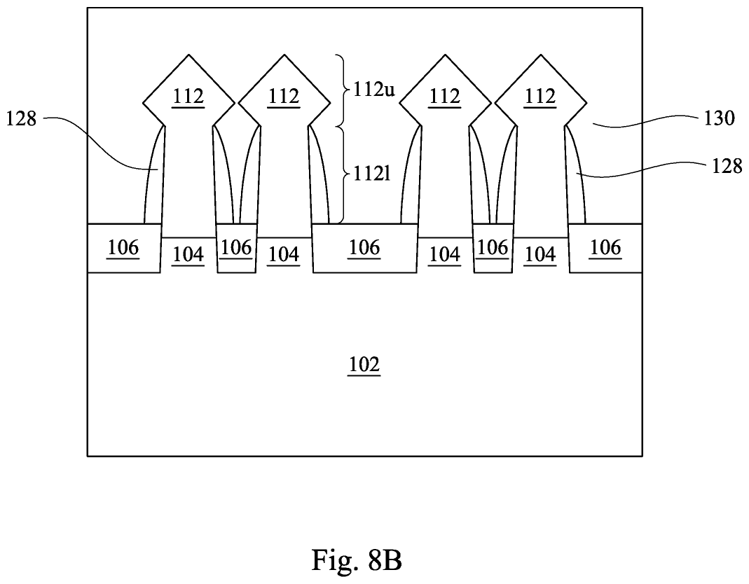

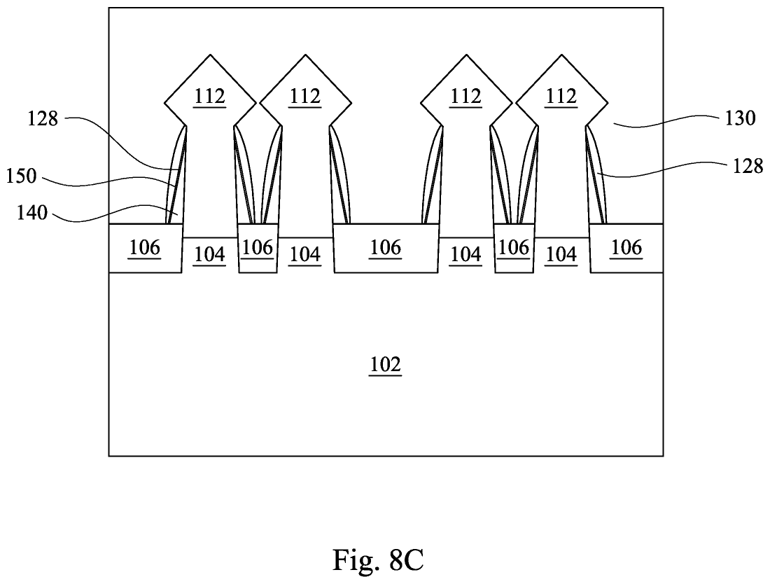

Reference is made to FIGS. 8A through 8C. FIG. 8A illustrates a cross-sectional view of the FinFET device 100 along cross-section A-A, FIG. 8B illustrates a cross-sectional view along cross-section C-C, and FIG. 8C illustrates a cross-sectional view along cross-section D-D.

After forming the surface modification layers 150, the gate dielectric layer 108 may be patterned to expose semiconductor fins 104. Subsequently, gate spacers 126 are formed on opposing sidewalls of the gate structures 122, and fin spacers 128 are formed on opposing sidewalls of the fins 104 and over the residues 140. As illustrated in FIGS. 8A through 8C, the gate spacers 126 and 128 are formed over the surface modification layer 150 covering the sidewalls 110s and the residues 140. In some embodiments, the spacers 126 and 128 are formed in same processing. For example, a spacer material layer is first deposited as a blanket layer over the substrate, and then the spacer material layer is anisotropically etched, such that horizontal portions of the spacer material layer are removed, while leaving portions of the spacer material layer on respective sidewalls of the dummy gate structures 122 and respective sidewalls of the fins 104.

The remaining portions of the spacer material layer conformally on sidewalls of the dummy gate structures 122 and the surface modification layer 150 are denoted as gate spacers 126 as illustrated in FIG. 8A, and the gate spacers 126 recess at levels of the gate dielectric layer 108 and the hard mask 121. The remaining portions of the spacer material layer on sidewalls of the fins 104 are denoted as fin spacers 128 as illustrated in FIGS. 8B and 8C.

The gate spacers 126 and fin spacers 128 may be formed of a nitride (e.g., silicon nitride), silicon oxynitride, silicon carbide, silicon carbonitride, the like, or a combination thereof, and may be deposited using, e.g., CVD, ALD or other suitable deposition processes. In some embodiments where the spacer material layer includes silicon nitride, the patterning of the silicon nitride layer includes a dry etching using CH₂F₂ as an etchant. In other embodiments in which the spacer material layer includes a silicon oxide layer and a silicon nitride layer, the patterning of the spacer material layer includes a dry etching using CH₂F₂ as an etchant to pattern silicon nitride, followed by a dry etching using CF₄ as an etchant to pattern the silicon oxide layer. The patterning includes an anisotropic effect, so that the horizontal portions of the spacer material layer are removed, while some vertical portions on the sidewalls of the dummy gate structures 122 remain to form gate spacers 126, and some vertical portions of the spacer material layer on the sidewalls of fins 104 remain to form fin spacers 128. In some embodiments, the process conditions for etching the spacer material layer are controlled to allow top ends of the fins 104 higher than top ends of the fins spacers 128.

Source/drain regions 112 are formed on exposed portions of the fins that are not covered by the dummy gate structures 122 and gate spacers 126. In some embodiments, formation of the source/drain regions 112 includes etching exposed portions of the fins 104 to form recesses in the fins, followed by epitaxially growing semiconductor materials in the recesses of the fins 104.

The exposed portions of the fins 104 can be recessed using suitable selective etching processing that attacks the semiconductor fin 104, but hardly attacks the gate spacers 126, fin spacers 128, and the top masks 121 of the dummy gate structures 122. For example, recessing the semiconductor fins 104 may be performed by a dry chemical etch with a plasma source and an etchant gas. The plasma source may be inductively coupled plasma (ICR) etch, transformer coupled plasma (TCP) etch, electron cyclotron resonance (ECR) etch, reactive ion etch (RIE), or the like and the etchant gas may be fluorine, chlorine, bromine, combinations thereof, or the like, which etches the semiconductor fins 104 at a faster etch rate than it etches the gate spacers 126, fin spacers 128, and the top masks 121 of the dummy gate structures 122. In some other embodiments, recessing the semiconductor fins 104 may be performed by a wet chemical etch, such as ammonium peroxide mixture (APM), NH₄OH, tetramethylammonium hydroxide (TMAH), combinations thereof, or the like, which etches the semiconductor fins 104 at a faster etch rate than it etches the gate spacers 126, fin spacers 128, and the top masks 121 of the dummy gate structures 122. In some other embodiments, recessing the semiconductor fins 104 may be performed by a combination of a dry chemical etch and a wet chemical etch.

Once recesses are created in the exposed regions of the fins 104, epitaxial structures 112 are formed in the source/drain recesses in the fins 104 to serve as source/drain regions 112 of transistors, by using one or more epitaxy or epitaxial (epi) processes that provides one or more epitaxial materials on the semiconductor fins 104. During the epitaxial growth process, the gate spacers 126 and fin spacers 128 limit the one or more epitaxial materials to exposed regions in the fins 104. As illustrated in FIGS. 8B and 8C, the epitaxial source/drain regions 112 may have surfaces raised from respective surfaces of the fins 104 (e.g. raised above the non-recessed portions of the fins 104) and may have facets. In some embodiments, the source/drain regions 112 epitaxially grown on adjacent fins 104 do not merge together and remain separate source/drain regions 112, as illustrated in FIGS. 8B and 8C. In some other embodiments, the source/drain regions 112 epitaxially grown on the adjacent fins 104 may merge to form a continuous epitaxial source/drain region 112.

In some embodiments, as illustrated in FIGS. 8B and 8C, the epitaxial material may be confined by the fin recess between the corresponding fin spacers 128 and the surface modification layers 150 and thus may have straight vertical or sloping sidewalls in between the fin spacers 128. Once the epitaxial material is grown to above the fin spacers 128, the epitaxial material will not be limited by the fin spacers 128 and thus form facets to have diamond shape. As a result, when viewed in a cross-sectional view taken along a direction perpendicular to longitudinal axes of fins 104 (e.g., FIG. 8C), each source/drain region 112 grown from a fin 104 has a lower portion 1121 confined between a corresponding pair of fin spacers 128, and an upper portion 112u free of confinement by the corresponding pair of fin spacers 128. The upper portion 112u has a different cross-sectional profile than the lower portion 1121. In particular, the upper portion 112u of each source/drain region 112 has a diamond cross-sectional profile, and the lower portion 1121 of each source/drain region 112 has a rectangular cross-sectional profile or a trapezoidal cross-sectional profile.

In some embodiments, the lattice constants of the epitaxy material of source/drain regions 112 are different from the lattice constant of the semiconductor fins 104, so that the channel regions in the fins 104 and between the source/drain regions 112 can be strained or stressed by the epitaxial material to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the semiconductor fins 104.

In some embodiments, the source/drain regions 112 may include Ge, Si, GaAs, AlGaAs, SiGe, GaAsP, SiP, or other suitable material. The source/drain regions 112 may be in-situ doped during the epitaxial process by introducing doping species including: p-type dopants, such as boron or BF2; n-type dopants, such as phosphorus or arsenic; and/or other suitable dopants including combinations thereof. If the source/drain epitaxial structures 112 are not in-situ doped, an implantation process (i.e., a junction implant process) is performed to dope the source/drain epitaxial structures 112. In some exemplary embodiments, the source/drain epitaxial structures 112 in an n-type transistor include SiP, while those in a p-type include GeSnB and/or SiGeSnB. In embodiments with different device types, a mask, such as a photoresist, may be formed over n-type device regions, while exposing p-type device regions, and p-type epitaxial structures may be formed on the exposed fins 104 in the p-type device regions. The mask may then be removed. Subsequently, a mask, such as a photoresist, may be formed over the p-type device region while exposing the n-type device regions, and n-type epitaxial structures may be formed on the exposed fins 104 in the n-type device region. The mask may then be removed.

Once the source/drain regions 112 are formed, an annealing process can be performed to activate the p-type dopants or n-type dopants in the source/drain regions 112. The annealing process may be, for example, a rapid thermal anneal (RTA), a laser anneal, a millisecond thermal annealing (MSA) process or the like.

After the source/drain regions 112 are formed, a first interlayer dielectric (ILD) 130 is formed over the structure illustrated in FIGS. 8A through 8C. In some embodiments, the first ILD 130 is formed of a dielectric material such as silicon oxide (SiO₂), phosphosilicate glass (PSG), borosilicate glass (BSG), boron-doped phosphosilicate Glass (BPSG), undoped silicate glass (USG), or the like, and may be deposited by any suitable method, such as CVD, PECVD, or FCVD.

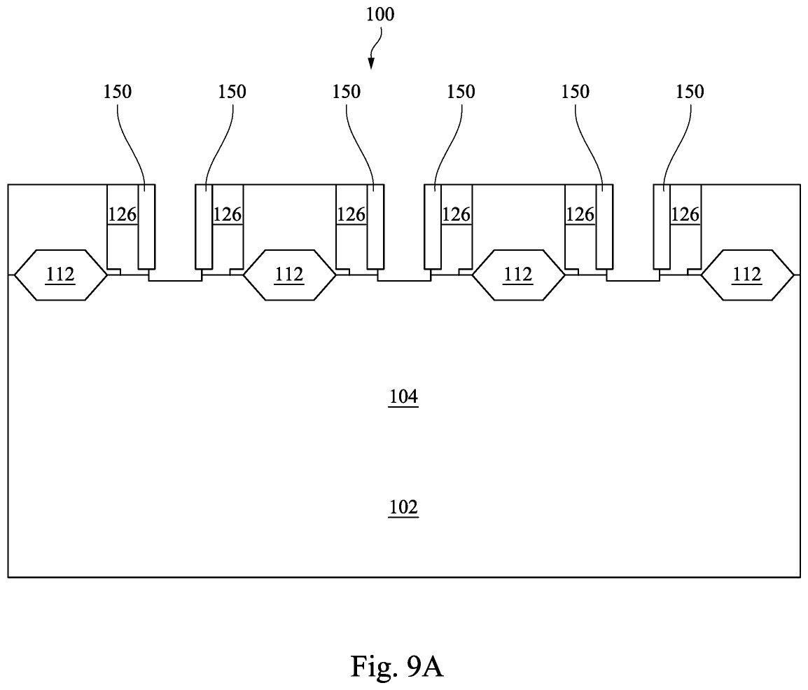

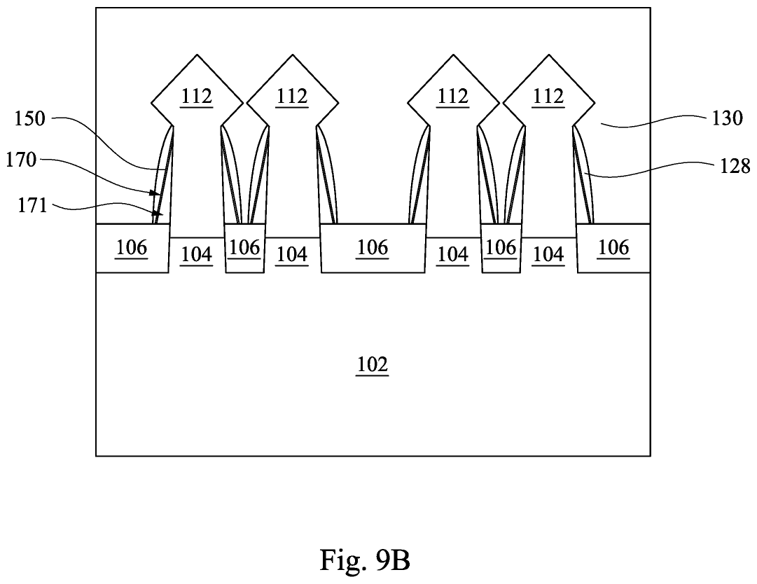

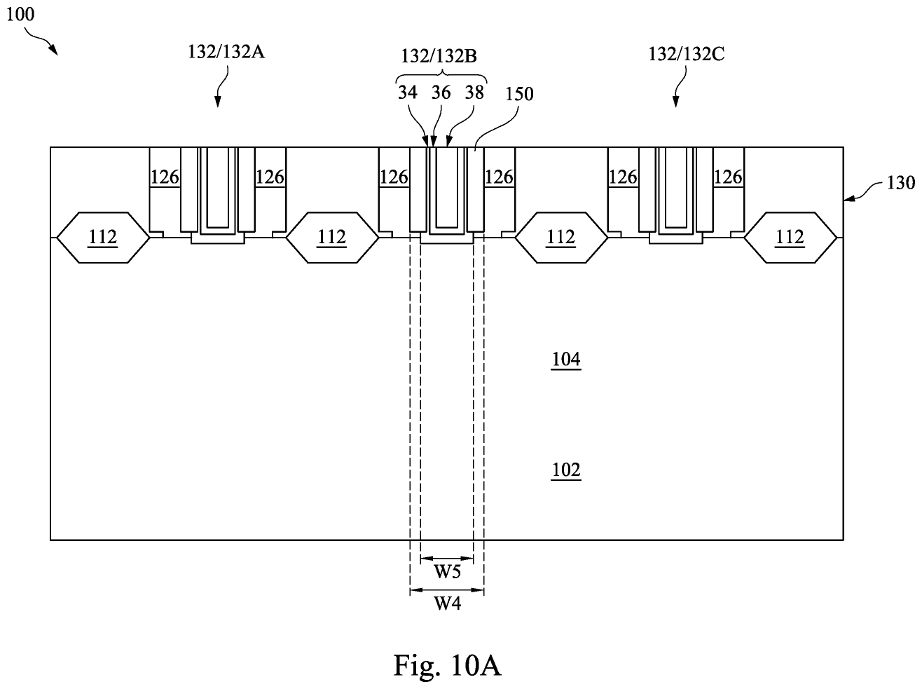

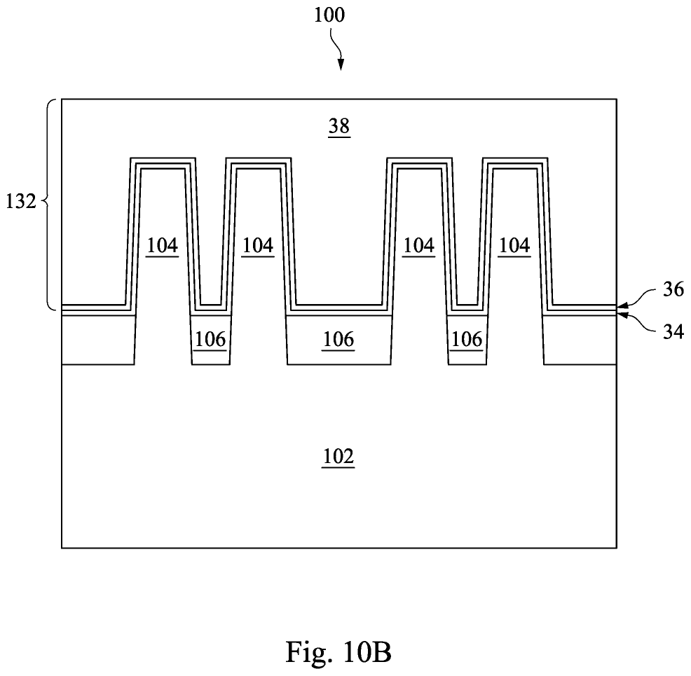

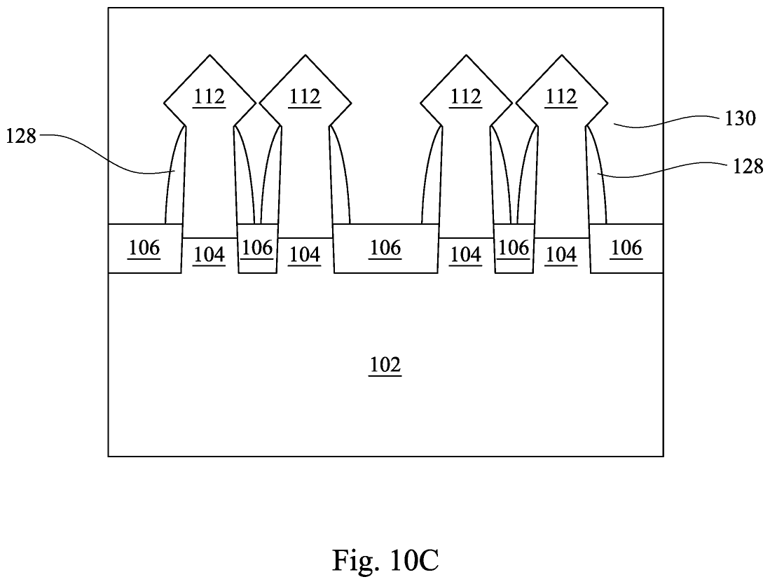

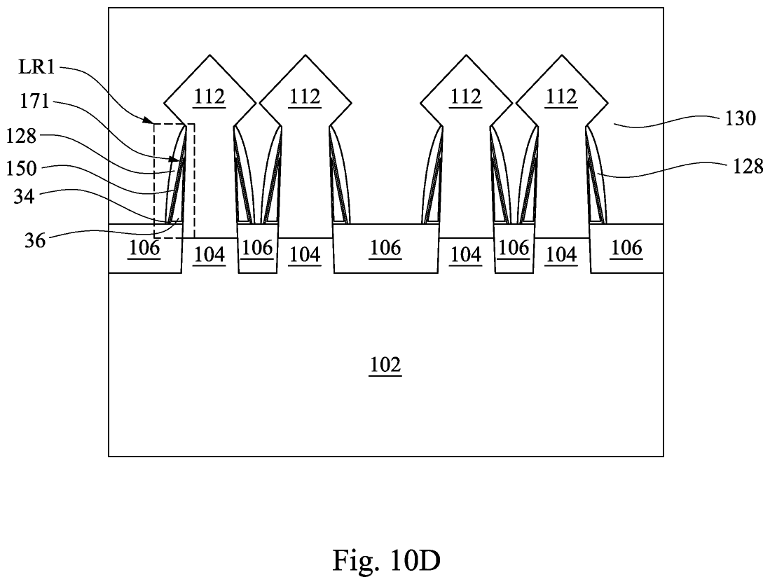

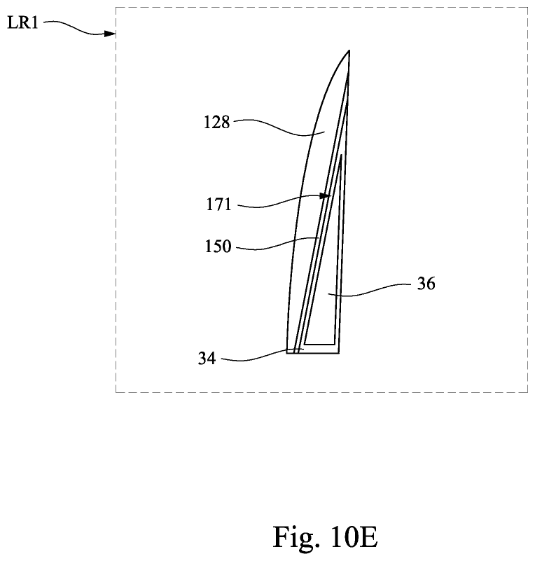

Reference is made to FIGS. 9A through 10E to illustrate planarization after forming the first ILD 130 and a gate-last process (sometimes referred to as replacement gate process). The dummy gate structures 122 are replaced with an active gate and an active gate dielectric, which may be collectively referred to as a replacement gate 132.

FIG. 9A illustrates a cross-sectional view of the FinFET device 100 along cross-section A-A, and FIG. 9B illustrates a cross-sectional view along cross-section D-D.

FIGS. 9A and 9B illustrate planarization after forming the first ILD 130 and removal of the dummy gate structure 122. In FIGS. 9A and 9B, a planarization process, such as CMP, may be performed to remove the mask 121 and to planarize the top surface of the first ILD 130, such that the top surface of the first ILD 130 is level with the top surface of the gate 110 after the CMP process. Therefore, after the CMP process, the top surface of the gate 110 may be exposed to be removed.

In order to replace the dummy gate structure 122 with an active gate and an active gate dielectric, which may be collectively referred to as a replacement gate, the gate layer 110 and the gate dielectric layer 108 are removed. In accordance with some embodiments, the gate 110 and the gate dielectric 108 directly under the gate 110 are removed in an etching step(s), so that gate trenches each are formed between a corresponding pair of gate spacers 126, as illustrated in FIG. 9A. Each gate trench exposes a channel region of a respective fin 104. The surface modification layers 150 in the gate trenches overlap the exposed top surfaces of the fins 104. Each channel region may be disposed between neighboring pairs of epitaxial source/drain regions 112. During the dummy gate removal, the dummy gate dielectric layer 108 may be used as an etch stop layer when the dummy gate 110 is etched. The dummy gate dielectric layer 108 may then be removed after the removal of the dummy gate 110.

Since the residues 140 of the gate layer 110 remain adjacent sidewalls of the source/drain regions 112 as illustrated in FIG. 8C, in FIG. 9B, the residues 140 are removed to form a plurality of gaps 170 formed by the fin spacers 128 and the source/drain regions 112 adjacent the gate trenches. Since the residues 140 of the gate layer 110 are spaced from each other before the residues 140 of the gate layer 110 are removed, the gaps 170 are isolated from each other as illustrated in the cross-section D-D of FIG. 9B. The surface modification layers 150 remain and occupy the gaps formed by the fin spacers 128 and the source/drain regions 112. In FIG. 9B, the surface modification layers 150 extend from sidewalls of the source/drain regions 112 to the top surface of the isolation regions 106. The surface modification layers 150, the sidewalls of the source/drain regions 112 and the top surface of the isolation regions 106 form a plurality of gaps 171 in the cross-sectional view as illustrated in FIG. 9B.

Reference is made to FIG. 10A through 10E to illustrate formation of replacement gates 132. FIG. 10A illustrates a cross-sectional view of the FinFET device 100 along cross-section A-A, FIG. 10B illustrates a cross-sectional view along cross-section B-B, FIG. 10C illustrates a cross-sectional view along cross-section C-C, FIG. 10D illustrates a cross-sectional view along cross-section D-D, and FIG. 10E illustrates a local region in FIG. 10D.

As illustrated in FIGS. 10A and 10B, high-k/metal gate structures 132 are formed in the gate trenches by forming a gate dielectric layer 34, a work function metal layer 36, and a gate electrode 38 successively in each of the gate trenches. In FIG. 10A, the gate dielectric layer 34 is deposited conformally in the gate trenches and between the surface modification layers 150 in the gate trenches. The work function metal layer 36 is formed conformally over the gate dielectric layer 34, and the gate electrode 38 fills the recesses. The gate dielectric layer 34 includes an interfacial layer (e.g., silicon oxide layer) and a high-k gate dielectric layer over the interfacial layer. High-k gate dielectrics, as used and described herein, include dielectric materials having a high dielectric constant, for example, greater than that of thermal silicon oxide (˜3.9). The work function metal layer 36 and/or gate electrode 38 used within high-k/metal gate structures 132 may include a metal, metal alloy, or metal silicide. Formation of the high-k/metal gate structures 132 may include multiple deposition processes to form various gate materials, one or more liner layers, followed by one or more CMP processes to remove excessive gate materials. After the one or more CMP processes are complete, gate materials remain in the gate trenches to serve as high-k/metal gate structures 132.

The high-k/metal gate structures 132 are replacement gate structures formed in respective gate trenches. The replacement gate structures 132 may be the final gates of FinFETs. The final gate structures each may be a high-k/metal gate stack, however other compositions are possible. In some embodiments, each of the replacement gate structures 132 forms the gate associated with the three-sides of a channel region provided by the fins 104. Stated another way, each of the replacement gate structures 132 wraps around channel regions of the fins 104 on three sides.

In some embodiments, the interfacial layer of the gate dielectric layer 34 may include a dielectric material such as silicon oxide (SiO₂), HfSiO, or silicon oxynitride (SiON). The interfacial layer may be formed by chemical oxidation, thermal oxidation, atomic layer deposition (ALD), chemical vapor deposition (CVD), and/or other suitable method. The high-k dielectric layer of the gate dielectric layer 34 may include hafnium oxide (HfO₂). Alternatively, the gate dielectric layer 34 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof.

The work function metal layer 36 may include work function metals to provide a suitable work function for the high-k/metal gate structures 132. For an n-type FinFET, the work function metal layer 36 may include one or more n-type work function metals (N-metal). The n-type work function metals may exemplarily include, but are not limited to, titanium aluminide (TiAl), titanium aluminium nitride (TiAIN), carbonitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AIC)), aluminides, and/or other suitable materials. On the other hand, for a p-type FinFET, the work function metal layer 3 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials.

In some embodiments, the gate electrode 38 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAIN, or other suitable materials.

In FIG. 10A, the gate spacers 126 and the surface modification layers 150 are on opposing sidewalls of each metal gate structure 132. The first ILD 130 laterally surrounds the metal gate structures 132 and the gate spacers 126. Three metal gate structures 132 (e.g., 132A, 132B, and 132C) are illustrated in the example of FIG. 10A. However, more or less than three metal gate structures 132 may be used to form the FinFET device 100, as skilled artisans readily appreciate.

In one or more embodiments, a combined structure of the gate structure 132 and the surface modification layer 150 have a width W4 at a level of a top of the gate structure 132 and a width W5 at a level of a bottom of the gate structure 132, and the width W5 is less than the width W4 as illustrated in FIG. 10A. The surface modification layer 150 has a bottom surface higher than a bottom surface of the gate spacer 126. The gate spacer 126 formed over the combined structure of the gate structure 132 and the surface modification layer 150 thus has a stepped sidewall structure including an upper sidewall and a lower sidewall laterally set back from the upper sidewall. The gate spacers 126 recess at the level of the bottom of the gate structure 132.

FIGS. 10B and 10C illustrate cross-sectional views of the FinFET device 100 of FIG. 10A, but along cross-section B-B and C-C of FIG. 1, respectively. In FIG. 10B, the metal gate structures 132 extend over the isolation regions 106 and the substrate 102.

FIG. 10D illustrates a cross-sectional view of the FinFET device 100 along cross-section D-D of FIG. 1, wherein FIG. 10D illustrates cross-sectional view between to the cross-section B-B and C-C. FIG. 10E illustrates a local region LR1 of FIG. 10D. As illustrated in FIGS. 10D and 10E, the gate dielectric layers 34 and the work function metal layers 36 extends into the gaps 171 formed by the surface modification layers 150, the sidewalls of the source/drain regions 112 and the top surface of the isolation regions 106. In some embodiments, the gate electrode layer 38 is free from the gaps 171 and absent between the surface modification layers 150 and the sidewall of the source/drain regions 112, thus reducing leakage current caused by the extension of the gate structure 132.

In one more embodiments of the present disclosure, the surface modification layers 150 may be formed by oxidizing dummy gate layer 110 such as polysilicon, and since the surface modification layers 150 are formed and occupy the gaps 170 between the source/drain regions 112 and the fin spacers 128 to form the gaps 171, the extension of the gate structure 132 between the source/drain regions 112 and the fin spacers 128 are reduced. In some embodiments, the dielectric constant of the surface modification layers 150 such as silicon oxide is less than high-k gate dielectrics in the gate structure 132. Parasitic capacitance caused by the extension of the gate structure 132 between the source/drain regions 112 and the fin spacers 128 can be reduced.

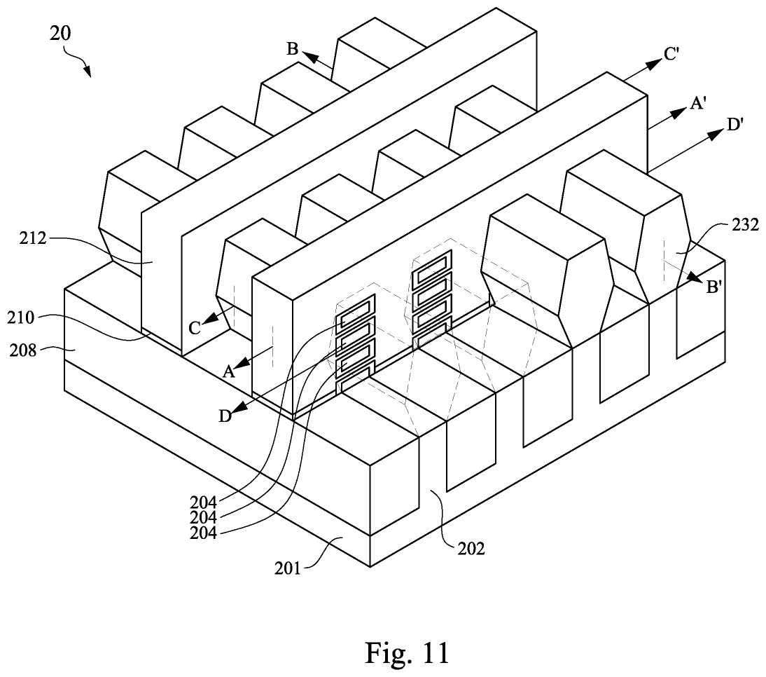

The surface modification of the dummy gate structure can also be used for formation of a gate-all-around (GAA) FET. Reference is made to FIGS. 11 through 13E to illustrate the surface modification layers for improving parasitic capacitance in the formed GAA-FET.

FIG. 11 illustrates an example of GAA-FETs 20 (e.g., nanowire FETs, nanosheet FETs, or the like) in a three-dimensional view, in accordance with some embodiments. The GAA-FETs 20 comprise nanostructures 204 (e.g., nanosheets, nanowires, nanorings, nanoslabs, or other structures having nano-scale size (e.g., a few nanometers)) over fins 202 on a substrate 201 (e.g., a semiconductor substrate), wherein the nanostructures 204 act as channel regions for the GAA-FETs 20. The nanostructure 204 may include p-type nanostructures, n-type nanostructures, or a combination thereof. Isolation regions 208 are disposed between adjacent fins 202, which may protrude above and from between neighboring Isolation regions 208. Although the Isolation regions 208 are described/illustrated as being separate from the substrate 201, as used herein, the term “substrate” may refer to the semiconductor substrate alone or a combination of the semiconductor substrate and the isolation regions. Additionally, although a bottom portion of the fins 202 are illustrated as being single, continuous materials with the substrate 201, the bottom portion of the fins 202 and/or the substrate 201 may comprise a single material or a plurality of materials. In FIG. 11, the fins 202 refer to the portion extending between the neighboring Isolation regions 208.

Gate dielectrics 210 are over top surfaces of the fins 202 and along top surfaces, sidewalls, and bottom surfaces of the nanostructures 204. Gate electrodes 212 are over the gate dielectrics 210. Epitaxial source/drain regions 232 are disposed on the fins 202 on opposing sides of the gate dielectric layers 210 and the gate electrodes 212.

FIG. 11 further illustrates reference cross-sections that are used in later figures. Cross-section A-A′ is along a longitudinal axis of a gate electrode 212 and in a direction, for example, perpendicular to the direction of current flow between the epitaxial source/drain regions 232 of a GAA-FET 20. Cross-section B-B′ is perpendicular to cross-section A-A′ and is parallel to a longitudinal axis of a fin 202 of the GAA-FET and in a direction of, for example, a current flow between the epitaxial source/drain regions 232 of the GAA-FET 20. Cross-section C-C′ is parallel to cross-section A-A′ and extends through epitaxial source/drain regions of the GAA-FETs 20. Cross-section D-D′ is parallel to cross-section A-A′ and is across a region between the gate electrode 212 and the source/drain regions 232. The GAA-FET 200 is similar to the GAA-FET 20 in FIG. 11 and subsequent figures refer to these reference cross-sections for clarity.

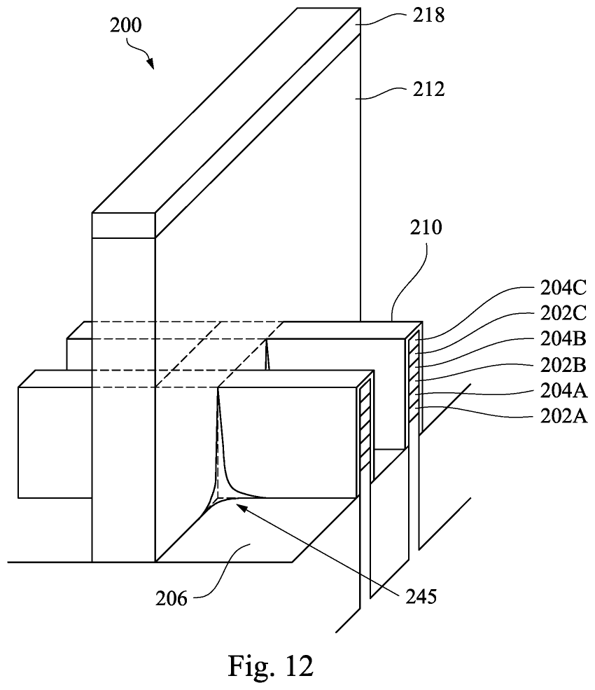

FIG. 12 illustrates a perspective view of forming a dummy gate structure to form a GAA-FET 200 (e.g., nanowire FETs, nanosheet FETs, or the like), in accordance with some embodiments. Sacrificial nanostructures 202A-C and nanostructures 204A-C are alternately stacked on fins extending from a semiconductor substrate 201. The sacrificial nanostructures 202A-C and nanostructures 204A-C may include semiconductor material such as silicon and/or germanium. In one or more embodiments, numbers of nanosheets alternately stacked fins extending from the semiconductor substrate 201 may be 2 to 6 layers of semiconductor sheets.

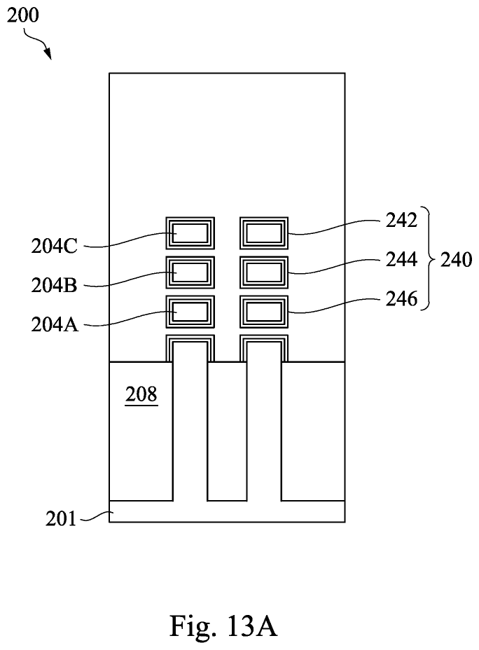

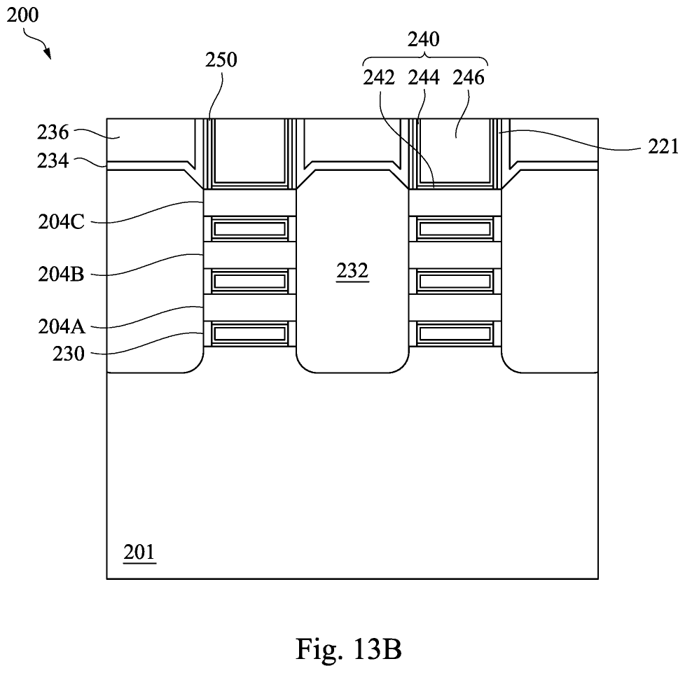

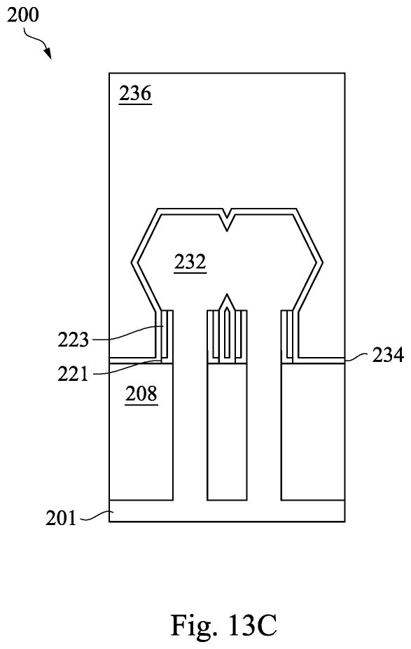

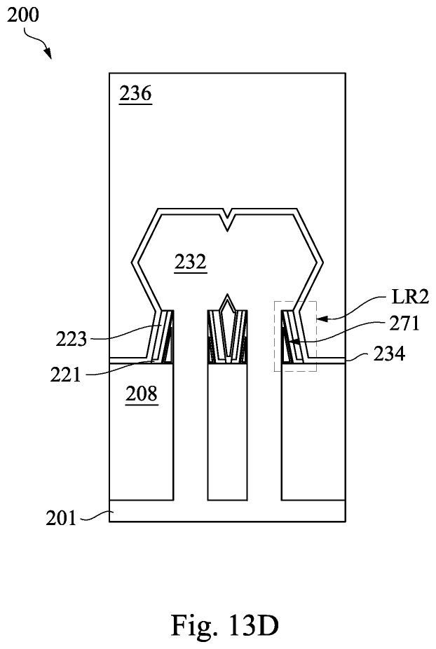

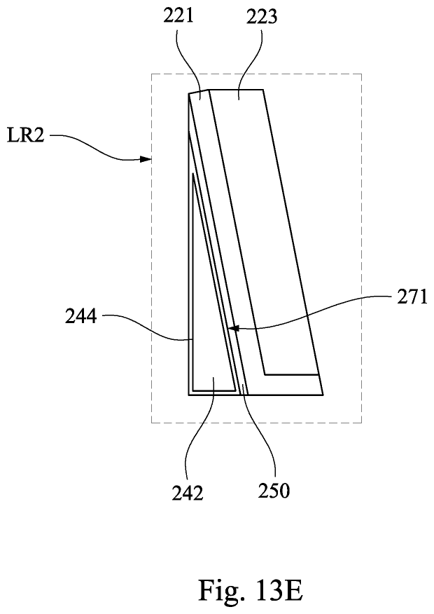

As illustrated in FIG. 12, a dummy gate dielectric layer 210, a dummy gate layer 212 and a patterned mask 218 are formed over the fin stack of sacrificial nanostructures 202A-C and nanostructures 204A-C. In FIG. 12, the dummy gate layer 212 is patterned and has residues 245 on the dummy gate dielectric layers 210 and extending out of the mask 218. In one or more embodiments of the present disclosure, exposed surface of the dummy gate dielectric layers 210 including the residues 245 may be modified and a plurality of surface modification layers 250 is formed to reduce the parasitic capacitance of the GAA-FET 200. Reference is made to FIGS. 13A through 13E to illustrate that the surface modification layers 250 are formed in the GAA-FET 200.

Reference is made to FIGS. 13A through 13E to illustrate cross-section view of the formed GAA-FET 200 with surface modification layers 250, which are formed by modify the dummy gate layers 210 using surface modification process similar to the surface modification process for converting exposed surfaces of the gate layer 110 into the surface modification layers 150 shown in FIGS. 7A through 7D, in accordance with one or more embodiments. FIG. 13A illustrates a cross-sectional view of the GAA-FET 200 along cross-section A-A′, FIG. 13B illustrates a cross-sectional view along cross-section B-B′, FIG. 13C illustrates a cross-sectional view along cross-section C-C′, FIG. 13D illustrates a cross-sectional view along cross-section D-D′, and FIG. 13E illustrates a local region LR2 in FIG. 13D.

In the stage of formation of the GAA-FET 200 in FIGS. 13A through 13E continuing from FIG. 12, the exposed surfaces of dummy gate layer 212 including residues 245 are modified to form a plurality of surface modification layers 250. The surface modification layers 250 may be trimmed and have reduced thickness in some embodiments.

Spacers 221 and 223 are formed over the surface modification layers 250. The sacrificial nanostructures 202A-C are etched back to form inner spacers 230 between the nanostructures 204A-C. After the inner spacers 230 are formed, source/drain recesses are formed by patterning the sacrificial nanostructures 202A-C and the nanostructures 204A-C. Source/drain regions 232 are formed by epitaxially growing semiconductor materials in the source/drain recesses of the fins 104 of the sacrificial nanostructures 202A-C and the nanostructures 204A-C. An interlayer dielectric (ILD) layer 236 is deposited over the source/drain regions 232. In some embodiments, a contact etch stop layer (CESL) 234 is disposed between the ILD layer 236 and the epitaxial source/drain regions 232, the masks 214, and the first spacers 221. The CESL 234 may comprise a dielectric material, such as, SiN, SiOₓ, SiCN, SiON, SiOCN, Al₂O₃, HfO₂, ZrO₂, HfAlOₓ, and HfSiOₓ, or the like, having a different etch rate than the material of the overlying ILD layer 236. A planarization process, such as a CMP, may be performed to level the top surface of the ILD layer 236 with the top surfaces of the dummy gate layers 212 or the masks 218. The planarization process may also remove the masks 218 on the dummy gate layers 212, and portions of the spacers 221 along sidewalls of the masks 218. After the planarization process, top surfaces of the dummy gate layers 212, the first spacers 221, and the ILD layer 236 are level within process variations. Accordingly, the top surfaces of the dummy gate layers 212 may be exposed through the ILD layer 236. The dummy gate structure having the dummy gate layers 212 and the dummy gate dielectric layer 210 and the sacrificial nanostructures 202A-C are then removed to form gate trenches, in which replacement gate structures 240 are respectively formed in to surround each of the suspended nanostructures 204A-204C.

The replacement gate structures 240 may be high-k metal gate including an interfacial layer 242 formed around the nanostructures 204A-204C, a high-k gate dielectric layer 244 formed around the interfacial layer 242 and a gate metal layer 246 formed around the high-k gate dielectric layer 244. Formation of the high-k/metal gate structures 240 may include one or more deposition processes to form various gate materials, followed by a CMP process to remove excessive gate materials. As illustrated in the cross-sectional view of FIGS. 13A through 13E, the high-k/metal gate structure 240 surrounds each of the nanostructures 204A-C, and thus is referred to as a gate of the GAA-FET 200.

The surface modification layers 250 formed by modifying the dummy gate layer 212 may remain in the formed GAA-FET 200 after the dummy gate layer 212 are removed. In FIG. 13B, the surface modification layers 250 remain between the gate structures 240 and the spacers 221. In FIG. 13D, the surface modification layers 250 corresponding to the residues 245 remain and extend between the spacers 221 and the source/drain regions 232. FIG. 13E illustrates a local region LR2 of the FIG. 13D. As illustrated in FIGS. 13D and 13E, the gate structures 240 extend between gaps formed by the spacers 221, the source/drain regions 232 and the isolation regions 208. The interfacial layer 242 and the high-k gate dielectric layer 244 of the gate structures 240 extend into the gaps 271. In some embodiments, the gate metal layers 246 as gate electrodes of the gate structures 240 are free from the gaps 271 and absent between the surface modification layers 250 and the sidewall of the source/drain regions 232.

According to one or more embodiments of the present disclosure, a method includes a number of operations. A method includes a number of operations. A semiconductor fin is formed and extends from a substrate. A dummy gate structure is formed across the semiconductor fin. An exposed surface of the gate layer is converted into a surface modification layer over the gate layer. Source/drain regions are formed on the semiconductor fin. The dummy gate structure is removed. A gate structure is formed over the semiconductor fin and extends between the source/drain regions and in the surface modification layer. In one or more embodiments, converting the exposed surface of the gate layer into the surface modification layer includes oxidizing the exposed surface of the gate layer. In some embodiments, oxidizing the exposed surface of the gate layer is performed by anneal. In some embodiments, the semiconductor fin is covered by a gate dielectric of the dummy gate when oxidizing the exposed surface of the gate layer. In one or more embodiments, the method further includes forming a spacer over the surface modification layer, wherein the surface modification layer is between the spacer and the source/drain regions. In some embodiments, forming the gate structure includes forming a high-k dielectric layer over the semiconductor fin, wherein the high-k dielectric layer extends between the source/drain regions and the surface modification layer. In one or more embodiments, the semiconductor fin includes a stack of nanostructures of different semiconductor materials.

According to one or more embodiments of the present disclosure, a method includes a number of operations. A gate dielectric layer is formed over a plurality of semiconductor fins. A gate layer is formed over the gate dielectric layer. The gate layer is patterned. A plurality of oxide layers is formed over the patterned gate layer by oxidizing the patterned gate layer, wherein the semiconductor fins are covered by the gate dielectric when oxidizing the gate layer. A spacer is formed over the oxide layers and the gate dielectric layer. Source/drain regions are formed on the semiconductor fins. The gate dielectric layer and the gate layer are removed. A gate structure is formed between the oxide layers. In one or more embodiments, oxidizing the gate layer includes a thermal anneal process. In some embodiments, the thermal anneal process is performed using an oxygen gas or oxygen radicals. In one or more embodiments, the method further includes forming a plurality of isolation regions between the semiconductor fins, wherein the oxide layers are formed over the isolation regions. In one or more embodiments, forming the gate structure includes forming a high-k dielectric layer between the oxide layers and filling with gaps formed by the oxide layers and source/drain regions and forming a gate electrode over the high-k dielectric layer. In one or more embodiments, the semiconductor fins include a stack of nanostructures of different semiconductor materials.

According to one or more embodiments of the present disclosure, a semiconductor device includes a channel region, source/drain regions on opposite sides of the channel region, a gate structure over the channel region, a gate spacer over a sidewall the gate structure and a first oxide layer between the gate structure and the gate spacer. The first oxide layer having a bottom surface higher than a bottom surface of the gate spacer. In one or more embodiments, the gate spacer has a stepped sidewall structure including an upper sidewall and a lower sidewall laterally set back from the upper sidewall. In one or more embodiments, the semiconductor device includes a fin spacer over a sidewall of the source/drain regions and a second oxide layer between the fin spacer and the sidewall of the source/drain regions. In some embodiments, the gate structure includes a gate dielectric layer between the second oxide layer and the sidewall of the source/drain regions. In some embodiments, the gate structure further includes a gate electrode over the gate dielectric and absent between the second oxide layer and the sidewall of the source/drain regions. In one or more embodiments, the first oxide layer is silicon oxide. In one or more embodiments, the channel region includes a plurality of nanosheets arranged one above another.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a semiconductor fin extending from a substrate;
forming a dummy gate structure across the semiconductor fin, wherein the dummy gate structure has a gate layer over the semiconductor fin;
converting an exposed surface of the gate layer into a surface modification layer over the gate layer;
forming source/drain regions on the semiconductor fin;
removing the dummy gate structure; and
forming a gate structure over the semiconductor fin and extending between the source/drain regions and in the surface modification layer.

2. The method of claim 1, wherein converting the exposed surface of the gate layer into the surface modification layer comprises oxidizing the exposed surface of the gate layer.

3. The method of claim 2, wherein oxidizing the exposed surface of the gate layer is performed by anneal.

4. The method of claim 2, wherein the semiconductor fin is covered by a gate dielectric of the dummy gate when oxidizing the exposed surface of the gate layer.

5. The method of claim 1, further comprising:
forming a spacer over the surface modification layer, wherein the surface modification layer is between the spacer and the source/drain regions.

6. The method of claim 5, wherein forming the gate structure comprises forming a high-k dielectric layer over the semiconductor fin, wherein the high-k dielectric layer extends between the source/drain regions and the surface modification layer.

7. The method of claim 1, wherein the semiconductor fin comprises a stack of nanostructures of different semiconductor materials.

8. A method comprising:
forming a gate dielectric layer over a plurality of semiconductor fins;
forming a gate layer over the gate dielectric layer;
patterning the gate layer;
forming a plurality of oxide layers over the patterned gate layer by oxidizing the patterned gate layer, wherein the semiconductor fins are covered by the gate dielectric when oxidizing the gate layer;
forming a spacer over the oxide layers and the gate dielectric layer;
forming source/drain regions on the semiconductor fins;
removing the gate dielectric layer and the gate layer; and
forming a gate structure between the oxide layers.

9. The method of claim 8, wherein oxidizing the gate layer includes a thermal anneal process.

10. The method of claim 9, wherein the thermal anneal process is performed using an oxygen gas or oxygen radicals.

11. The method of claim 8, further comprising:
forming a plurality of isolation regions between the semiconductor fins, wherein the oxide layers are formed over the isolation regions.

12. The method of claim 8, wherein forming the gate structure comprises:
forming a high-k dielectric layer between the oxide layers and filling with gaps formed by the oxide layers and source/drain regions; and
forming a gate electrode over the high-k dielectric layer.

13. The method of claim 8, wherein the semiconductor fins comprise a stack of nanostructures of different semiconductor materials.

14. A semiconductor device comprising:
a channel region;
source/drain regions on opposite sides of the channel region;
a gate structure over the channel region;
a gate spacer over a sidewall the gate structure; and
a first oxide layer between the gate structure and the gate spacer, the first oxide layer having a bottom surface higher than a bottom surface of the gate spacer.

15. The semiconductor device of claim 14, wherein the gate spacer has a stepped sidewall structure comprising an upper sidewall and a lower sidewall laterally set back from the upper sidewall.

16. The semiconductor device of claim 14, further comprising:
a fin spacer over a sidewall of the source/drain regions; and
a second oxide layer between the fin spacer and the sidewall of the source/drain regions.

17. The semiconductor device of claim 16, wherein the gate structure comprises a gate dielectric layer between the second oxide layer and the sidewall of the source/drain regions.

18. The semiconductor device of claim 17, wherein the gate structure further comprises a gate electrode over the gate dielectric and absent between the second oxide layer and the sidewall of the source/drain regions.

19. The semiconductor device of claim 14, wherein the first oxide layer is silicon oxide.

20. The semiconductor device of claim 14, wherein the channel region comprises a plurality of nanosheets arranged one above another.
